(19) United States
(12) Patent Application Publication
(10) Pub. No.: US 2010/0184253 A1
(43) Pub. Date: Jul. 22, 2010

(54) PROCESS FOR MANUFACTURING THIN FILM TRANSISTOR

(75) Inventors: Katsura Hirai, Tokyo (JP); Makoto Honda, Tokyo (JP)

Correspondence Address: CANTOR COLBURN, LLP, 20 Church Street, 22nd Floor, Hartford, CT, 06103, US

(73) Assignee: KONICA MINOLTA HOLDINGS, INC., Tokyo (JP)

(21) Appl. No.: 12/487,954

(22) Filed: Jun. 19, 2009

(30) Foreign Application Priority Data
Jun. 24, 2008 (JP) 2008-164212

(51) Int. Cl. H01L 21/36

(52) U.S. Cl. 438/104; 257/E21.461

(57) ABSTRACT

Disclosed is a process for manufacturing a thin film transistor, the process comprising the steps of providing an oxide semiconductor precursor solution for an oxide semiconductor layer in which an oxide semiconductor precursor is dissolved in a solvent, coating the oxide semiconductor precursor solution on a substrate to form an oxide semiconductor precursor layer, patterning the oxide semiconductor precursor layer so that the oxide semiconductor precursor layer remains at portions where the oxide semiconductor layer is to be formed, and heating the remaining oxide semiconductor precursor layer to form the oxide semiconductor layer.

This application is based on Japanese Patent Application No. 2008-164212, filed on Jun. 24, 2008 in Japanese Patent Office, the entire content of which is hereby incorporated by reference.

### FIELD OF THE INVENTION

The present invention relates to a process for manufacturing a thin film transistor in which an oxide semiconductor is formed from a precursor.

### BACKGROUND OF THE INVENTION

In a thin film transistor, a manufacturing process of a thin film transistor is known which comprises converting a semiconductor precursor to a semiconductor.

As a technique of converting a metal layer to an oxide semiconductor layer, for example, an attempt is made in which a layer of a metal such as Cu, Zn or Al formed on a substrate is subjected to thermal oxidation or plasma oxidation to convert to an oxide semiconductor layer (see, for example, Japanese Patent O.P.I. Publication Nos. 8-264794). In is also described as a dopant.

A technique is also known in which an organometallic compound is subjected to oxidation decomposition (heat decomposition reaction) to form an amorphous oxide (see, for example, Japanese Patent O.P.I. Publication No. 2003-179242).

In a general patterning method of an oxide semiconductor, an oxide semiconductor formed according to for example, sputtering is subjected to patterning.

### SUMMARY OF THE INVENTION

An object of the invention is to provide a process of manufacturing a thin film transistor employing a simply means, the process comprising forming a semiconductor layer as an active layer. The thin film transistor manufacturing process of the invention comprises the steps of providing an oxide semiconductor precursor solution for an oxide semiconductor layer in which an oxide semiconductor precursor is dissolved in a solvent, coating the oxide semiconductor precursor solution on a substrate to form an oxide semiconductor precursor layer, patterning the oxide semiconductor precursor layer so that the oxide semiconductor precursor layer remains at portions where the oxide semiconductor layer is to be formed, and heating the remaining oxide semiconductor precursor layer to form the oxide semiconductor layer.

### BRIEF EXPLANATION OF THE DRAWINGS

FIGS. 1.1 through 1.7 are sectional views showing one manufacturing process of the thin film transistor of the invention.

FIGS. 2.1 through 2.7 are sectional views showing another manufacturing process of the thin film transistor of the invention

FIGS. 3a through 3c are sectional views showing the structure of a top gate type thin film transistor.

FIGS. 3d through 3f are sectional views showing the structure of a bottom gate type thin film transistor.

FIG. 4 is a schematic equivalent circuit diagram of one example of a thin-film transistor sheet in which plural TFTs are arranged.

### DETAILED DESCRIPTION OF THE INVENTION

The above object of the invention can be attained by any one of the following constitutions.

1. A process for manufacturing a thin film transistor, the process comprising the steps of providing an oxide semiconductor precursor solution for an oxide semiconductor layer in which an oxide semiconductor precursor is dissolved in a solvent, coating the oxide semiconductor precursor solution on a substrate to form an oxide semiconductor precursor layer, patterning the oxide semiconductor precursor layer so that the oxide semiconductor precursor layer remains at portions where the oxide semiconductor layer is to be formed, and heating the remaining oxide semiconductor precursor layer to form the oxide semiconductor layer.

2. The process of item 1 above, wherein the solvent is at least one selected from the group consisting of water, ethanol, propanol, ethylene glycol, tetrahydrofuran, dioxane, methyl acetate, ethyl acetate, acetone, methyl ethyl ketone, cyclohexanone, diethylene glycol monomethyl ether, acetonitrile, xylene, toluene, o-dichlorobenzene, nitrobenzene, meta-cresol, hexane, cyclohexane, tridecane, α-terpineol, chloroform, 1,2-dichloroethane, N-methylpyrrolidone and carbon disulfide.

3. The process of item 1 above, wherein the solvent contains 50% or more by weight of water or 50% by weight or more of alcohol.

4. The process of item 1 above, wherein the coating is carried out according to a spin coating method, a spray coating method, a blade coating method, a dip coating method, a cast coating method, a bar coating method, a die coating method, letterpress printing, intaglio printing, lithographic printing, screen printing or ink jetting.

5. The process of item 1 above, wherein the patterning comprises employing an ink jet method, a screen printing method, an ablation method or a photoresist method.

G. The process of item 1 above, wherein the patterning comprises the steps of forming a photoresist layer on the oxide semiconductor precursor layer; pattern-wise exposing the photoresist layer; and developing the exposed photoresist layer with a developing solution so that the photoresist layer on the oxide semiconductor precursor layer at portions where the oxide semiconductor layer is to be formed remains unremoved and an unnecessary oxide semiconductor precursor layer is removed during development.

7. The process of item 6 above, wherein the photoresist layer is formed from a negative working photoresist, a positive working photoresist or a laser-sensitive photoresist.

8. The process of item 6 above, wherein the developing solution contains 50% or more by weight of water or 50% by weight or more of alcohol.

9. The process of item 6 above, after the heating, further comprising the step of removing the remaining photoresist layer with a solution containing at least one selected from the group consisting of alcohols, ethers, esters, ketones and glycol ethers.

10. The process of item 9 above, wherein the solution contains ketones.

11. The process of item 1 above, wherein the heating is carried out employing at least one selected from an infrared heater, an electric oven, a dry heat block and a microwave.

12. The process of item 1 above, wherein the heating comprises is carried out according to at least irradiation of microwave with a frequency of from 0.3 to 50 GHz.

13. The process of item 1 above, wherein the oxide semiconductor precursor comprises a metal ion of In, Sn or Zn.

14. The process item 1 above, wherein the oxide semiconductor precursor comprises a metal ion of Ga or Al.

15. The process of item 1 above, wherein the oxide semiconductor precursor comprises at least one metal salt selected from the group consisting of a metal nitrate, a metal sulfate, a metal phosphate, a metal carbonate, a metal acetate and a metal oxalate.

16. The process of item 15 above, wherein the oxide semiconductor precursor comprises a metal nitrate.

17. The process of item 1 above, wherein the oxide semiconductor precursor solution contains metal A, metal B, and metal C so as to satisfy the following formula,

metal A:metal B:metal C=1:0.2 to 1.5:0 to 5 (by mole)

wherein metal A denotes a metal contained in a metal salt selected from indium salts and tin salts; metal B denotes a metal contained in a metal salt selected from gallium salts and aluminum salts; and metal C denotes a metal contained in a metal salt selected from zinc salts.

18. The process of item 17 above, wherein the metal A is indium, the metal B is gallium, and the metal C is zinc.

19. The process of item 1 above, wherein the oxide semiconductor precursor comprises indium nitrate, gallium nitrate and zinc nitrate, the solvent contains 50% by weight or more of water or 50% by weight or more of alcohol, and the heating is carried out according to irradiation of microwave with a frequency of from 0.3 to 50 GHz.

20. The process of item 19 above, wherein the solvent contains 50% by weight or more of water.

The present invention can provide a process of manufacturing a thin film transistor with high mobility and excellent on/off ratio, employing a simply means, the transistor comprising a semiconductor layer as an active layer.

Next, the preferred embodiment of the present invention will be explained in detail.

The invention is a process comprising the steps of forming an oxide semiconductor precursor layer by coating, patterning the oxide semiconductor precursor layer in the form of an oxide semiconductor layer, and heating the patterned layer, whereby an oxide semiconductor layer is easily formed.

The oxide semiconductor layer as an active layer of a thin film transistor, which is manufactured according to the above-described process, provides a thin film transistor with high mobility.

In the invention, the active layer means a semiconductor layer forming a channel in a thin film transistor which is activated by electric field application to increase mobility, whereby operation such as switching is conducted.

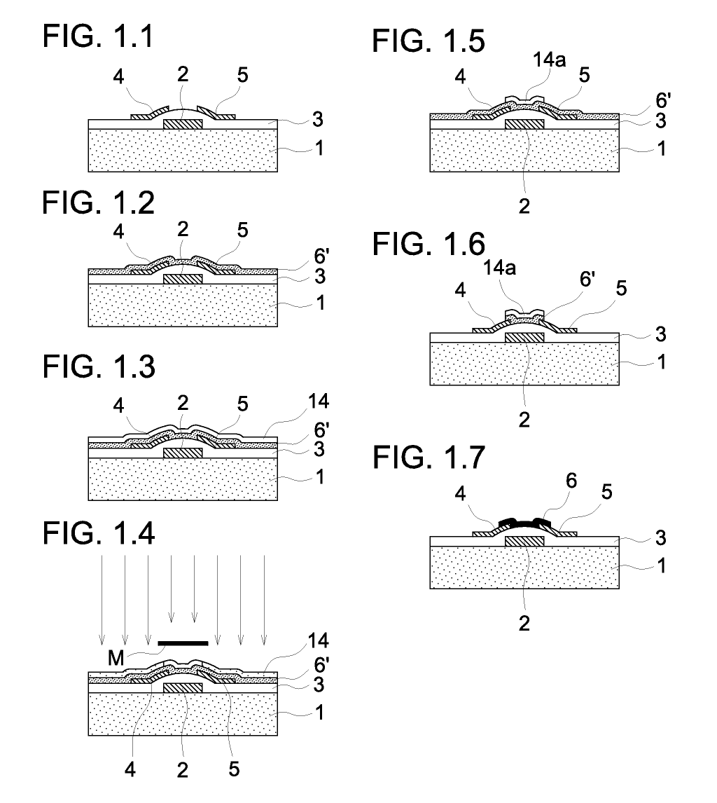

Next, the process of the invention for manufacturing a thin film transistor will be explained employing FIG. 1.

The oxide semiconductor precursor is, for example, metal nitrates etc., and will be detailed later. For example, an aqueous solution of a mixture of indium nitrate, zinc nitrate and gallium nitrate (indium nitrate:zinc nitrate:gallium nitrate=1:1:1 by mole in terms of metal) is employed as a semiconductor precursor solution.

Firstly, the semiconductor precursor solution is uniformly coated on a substrate according to a wet process such as coating (FIG. 1.2).

In the above, as the substrate are used, for example, a glass substrate 1 as shown in FIG. 1.1, on which a gate electrode 2, a gate insulating layer 3, a source electrode 4 and a drain electrode 5 are provided. That is, a semiconductor precursor layer 6′ is uniformly formed on the substrate by coating (FIG. 1.2).

The precursor layer is sufficiently dried, followed by patterning employing a resist.

As the patterning methods employing a resist, there are various methods such as an ink jet method, a screen printing method and an ablation method, whereby the resist is formed on a substrate. The simplest method is a photoresist method.

A negative or positive working photoresist known in the art may be utilized for a photoresist layer employed in the photoresist method, but a light sensitive resin, particularly a laser-sensitive photoresist is preferably utilized.

Materials for the photoresist include (1) photopolymerizable light sensitive materials of a dye-sensitized type as described in Japanese Patent O.P.I. Publication Nos. 11-271959, 2001-117219, 11-311859, and 11-352691; (2) negative working light sensitive materials featuring infrared laser sensitivity as described in Japanese Patent O.P.I. Publication No. 9-179292, U.S. Pat. No. 5,340,699, Japanese Patent O.P.I. Publication Nos. 10-90885, 2000-321780, and 2001-154374; and (3) positive working light sensitive materials featuring infrared laser sensitivity as described in Japanese Patent O.P.I. Publication Nos. 9-171254, 5-115144, 10-87733, 9-43847, 10-268512, 11-194504, 11-223936, 11-84657, 11-174681, 7-285275, and 2000-56452, and WO 97/39894 and 98/42507.

A method for providing a photoresist 14 on the semiconductor precursor layer 6′ (FIG. 1.3) is not specifically limited and may be any known method. For example, a UV sensitive resin can be coated as the photoresist on the semiconductor precursor layer 6′ according to a spin coating method. The thickness of the photoresist 14 is not specifically limited and can be determined considering development of the photoresist or removal of an unnecessary semiconductor precursor layer employing the photoresist as a mask.

Employing a mask aligner which is an apparatus capable of carrying out exposure after the position of a photomask and the substrate having a semiconductor precursor layer 6′ is determined, the photoresist 14 provided on the substrate is subjected to pattern exposure through a photo mask installed in a mask aligner (FIG. 1.4). When the photoresist is positive-working, the photomask is arranged so that the photoresist on a region other than the semiconductor channel region is exposed. When the photoresist is negative-working, the photomask is arranged so that the photoresist on the semiconductor channel region is exposed. Successively, the photoresist 14 is developed with a developing solution to obtain a photoresist pattern 14a, followed by removal of the semiconductor precursor layer employing the photoresist pattern 14a as a mask, whereby removal (cleaning) of an unnecessary semiconductor precursor layer can be carried out (FIGS. 1.5 and 1.6).

The removal of the precursor layer can be carried out employing a known method according to kinds of the precursor. A solvent dissolving the precursor, for example, a solvent used in a precursor coating solution can be used. The unnecessary semiconductor precursor layer can be removed by cleaning treatment of dipping the precursor layer in the solvent.

Herein, when the photoresist is developed with a developing solution (particularly an aqueous alkaline solution), the semiconductor precursor layer 6′ at portions where the photoresist has been removed is dissolved in the developing solution and removed with the development of the photoresist.

Herein, the semiconductor precursor layer 6′ which has been patterned remains on the substrate as a constituent of a thin film transistor (FIG. 1.6).

The development of the photoresist and removal of the semiconductor precursor layer 6′ may be separately carried out employing a different solvent. A solvent for dissolving the semiconductor precursor layer 6′ can be employed as long as it dissolves the semiconductor precursor but does not dissolve the photoresist.

However, it is preferred that the semiconductor precursor layer be removed with the development of the photoresist. As a developing solution used for development of the photoresist, an aqueous alkaline developing solution (described later) is preferred.

When the aqueous alkaline solution is used, the photoresist at exposed portions is removed and at the same time the semiconductor precursor layer at portions where the photoresist has been removed is removed (FIG. 1.6).

Examples of the aqueous alkaline developing solution include, for example, aqueous solutions of alkali metal salts such as sodium hydroxide, potassium hydroxide, sodium carbonate, potassium carbonate, sodium metasilicate, potassium metasilicate, sodium secondary phosphate, or sodium tertiary phosphate; and aqueous solutions prepared by dissolving alkali compounds such as ammonia, ethylamine, n-propylamine, diethylamine, di-n-propylamine, triethylamine, methyldiethylamine, dimethylethanolamine, triethanolamine, tetramethylammonium hydroxide, piperidine, 1,8-diazabicyclo-[5,4,0]-7-undecene or 1,5-diazabicyclo-[4,3,0]-5-nonane. The concentration of the alkali compound in the alkaline developing solution in the present invention is ordinarily from 1 to 10% by weight, and preferably from 2 to 5% by weight.

An anionic surfactant, an amphoteric surfactant or an organic solvent such as alcohol may optionally be added in the developing solution.

Examples of the organic solvent include propylene glycol, ethylene glycol monophenyl ether, benzyl alcohol, and n-propyl alcohol.

The oxide semiconductor precursor layer after patterning is heated to convert to an oxide semiconductor layer 6. The conversion of the precursor to oxide semiconductor due to heat application basically results from thermal oxidation, and the heat application is carried out in the presence of oxygen in an ambient atmosphere.

In the present invention, the temperature to heat the precursor can be arbitrarily selected from the range of from 50 to 1000° C. in terms of the surface temperature of a layer containing the precursor. The temperature is preferably from 100 to 400° C. and more preferably from 200 to 350° C. in view of device performance or productivity of an electronic device. The surface temperature of the layer or the temperature of a substrate can be measured by, for example, a surface thermometer having a thermocouple, a radiation thermometer which can measure a radiation temperature and a fiber thermometer. The heating temperature can be controlled by the output power of the electromagnetic wave, the duration of the irradiation and the number of times of the irradiation. The heating duration of the precursor can be arbitrarily selected, however, the heating duration is preferably from 1 second to 60 minutes in view of device performance or productivity of an electronic device. The heating duration is more preferably from 5 minutes to 30 minutes. The heat application is carried out through any appropriate heat application means such as an infrared heater, various kinds of electric ovens, a dry heat block, a microwave oven and various kinds of heaters. However, the heat application means are not limited thereto. Microwave irradiation to be described later is preferably employed.

### (Microwave Irradiation)

In the present invention, it is preferable to use microwave irradiation as a method to convert a layer formed from a metal compound used as an oxide semiconductor precursor into a semiconductor layer. The microwave irradiation may be carried out singly or in combination with other heating means.

That is, after a layer is formed which contains the metal compound used as the oxide semiconductor precursor, the layer is subjected to irradiation of an electromagnetic wave, specifically, with a microwave (with a frequency of from 0.3 to 50 GHz).

When the layer containing the metal compound used as the precursor of a metal oxide semiconductor is irradiated with a microwave, electrons in the metal oxide precursor vibrate to generate heat, whereby the inside of the layer is uniformly heated. Since a substrate made of glass or resin has no microwave absorption, the substrate itself is hardly heated, and only the layer on the substrate is selectively heated to cause thermal oxidation, resulting in conversion of the precursor to a metal oxide semiconductor.

As is the case with microwave heating, absorption of the microwave is concentrated on a material having strong microwave absorption to elevate the temperature in a very short time. Accordingly, when this technique is applied to the present invention, the electromagnetic wave has no influence on the substrate and elevates a temperature of only the precursor layer to a temperature at which oxidation reaction occurs, whereby the oxide precursor can be converted to a metal oxide. Further, the heating temperature and heating duration can be controlled by the output power and irradiation time of the microwave and adjusted according to kinds of the precursor or the substrate used.

Generally a microwave refers to an electromagnetic wave within the frequency range of from 0.3 to 50 GHz. All of the frequencies 0.8 GHz and 1.5 GHz bands, 2 GHz band for mobile-phone communication, 1.2 GHz band for ham radio, aircraft radar, etc., 2.4 GHz band for microwave oven, premises wireless or VICS, etc., 3 GHz band for marine vessel radar, etc. and 5.6 GHz band for ETC are included in the category of the microwave. Oscillators with a frequency of 28 GHz or 50 GHz are commercially available.

When compared with an ordinary heating method using, for example, an oven, the heating method employing electromagnetic wave (microwave) irradiation provides a more preferable metal oxide semiconductor layer. During conversion of an oxide semiconductor precursor to an oxide semiconductor, an effect suggesting an action other than the thermal-conduction, for example, a direct action of the electromagnetic wave to the oxide semiconductor precursor is obtained. Although the mechanism is not fully clear, it is assumed that the conversion of the oxide semiconductor precursor to the oxide semiconductor via hydrolysis, dehydration, decomposition or oxidation is promoted by the electromagnetic wave.

The method to irradiate a semiconductor precursor layer containing the metal compound with a microwave to carry out conversion to a semiconductor layer is a method in which oxidation reaction is selectively conducted in a short time. In order to promote the oxidation reaction of the oxide semiconductor precursor in a short time, it is preferred that the microwave irradiation be carried out in the presence of oxygen. It is also preferred that since not a small amount of heat may be transferred to the substrate through thermal conduction, the surface temperature of the layer containing a precursor is heat treated to be within the temperature range of from 100 to 400° C. by controlling the output power or the duration of irradiation or the number of times of irradiation, particularly when a substrate having a low heat-resistance such as a resin substrate is used. The temperature of the layer surface or of the substrate can be measured with a surface thermometer having a thermocouple or a non-contact surface thermometer.

Further, when a strong electromagnetic wave absorber such as ITO is provided in the vicinity (for example, a gate electrode), it also absorbs the microwave and generates heat, whereby the vicinity area thereof can be heated in a short time.

The oxide semiconductor thin film formed from metal oxide can be use for various semiconductor devices such as a transistor and a diode, as well as an electronic circuit. A method comprising coating a solution of a semiconductor precursor on a substrate makes it possible to form an oxide semiconductor layer at a low temperature, and the method can be preferably applied to production of a semiconductor device such as a thin film transistor element (TFT element) using a resin substrate.

The metal oxide semiconductor can be also applied to a diode or a photosensor. For example, a schottky diode or a photodiode may also be manufactured by laminating the metal oxide semiconductor with a metal thin film composed of an electrode material to be described later.

After the remaining photoresist pattern is removed, heating treatment is carried out in the presence of oxygen, whereby the semiconductor precursor layer 6′ is converted to a semiconductor layer 6. Thus, a thin film transistor is prepared. The order of removing the photoresist pattern is not limited to the above, that is, the remaining photoresist may be removed after the semiconductor precursor layer 6′ is heat treated in the presence of oxygen to convert to the semiconductor layer 6.

A thin film transistor having a photoresist can function as a thin film transistor. However, the remaining photoresist pattern 14a can be removed by dipping in an organic solvent or by oxygen plasma asking. When the photoresist pattern 14a is removed, a method should be selected in which has no adverse influence on the oxide semiconductor layer or another constituent layer provided on the substrate. Generally, the photoresist pattern is removed employing for example, an organic solvent.

As a solvent for removing the photoresist, an organic solvent can be used which is selected from a wide range of organic solvents including alcohols, ethers, esters, ketones, or glycol ethers which are used for a coating solvent for photoresist. Ether solvents or ketone solvents are preferred, since they have no adverse influence on the oxide semiconductor layer or another constituent layer provided on the substrate during removal of the photoresist. Ether solvents such as THF are more preferred.

The thus obtained thin film transistor is provided on a display element or a function element, and the photoresist pattern is preferably removed. FIG. 1.7 shows a sectional view of the thin film transistor.

In the above, a manufacturing process of a bottom gate and top contact type thin film transistor is described. However, the process of the invention is limited to the above-described transistor as long as it is employed at the formation of an active layer, i.e., a semiconductor layer of a thin film transistor.

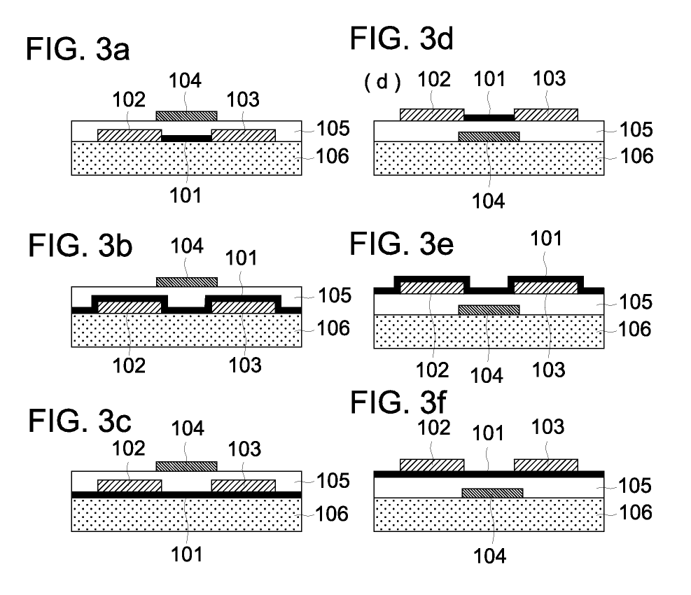

FIGS. 3a through 3f are sectional views showing the structure of thin film transistors manufactured according to the thin film transistor manufacturing process of the invention.

FIGS. 3a through 3c are sectional views showing the structure of top gate type thin film transistors.

FIG. 3a is a field-effect transistor in which a source electrode 102 and a drain electrode 103 are formed on a support 106 to obtain a substrate, a semiconductor layer 101 is formed between both electrodes on the substrate, an insulating layer 105 is formed over the substrate, and a gate electrode 104 is formed on the insulating layer. FIG. 3b is a field-effect transistor which has the same structure as FIG. 3a, except that a semiconductor layer 101 is formed to cover the electrodes and the entire surface of the substrate. FIG. 3c is a field-effect transistor in which a semiconductor layer 101 is formed on the support 106, followed by formation of a source electrode 102 and a drain electrode 103, an insulating layer 105, and a gate electrode 104 in that order.

FIGS. 3d through 3f are sectional views showing the structure of bottom gate type thin film transistors. FIG. 3d is a field-effect transistor in which a gate electrode 104 and an insulating layer 105 are formed on a support 106 to obtain a substrate, a source electrode 102 and a drain electrode 103 are formed on the substrate, and a semiconductor layer 101 is formed between both electrodes. Another a field-effect transistor has the structure as shown in FIGS. 3e and 3f.

The present invention can be applied to formation of a semiconductor layer as shown in this figure.

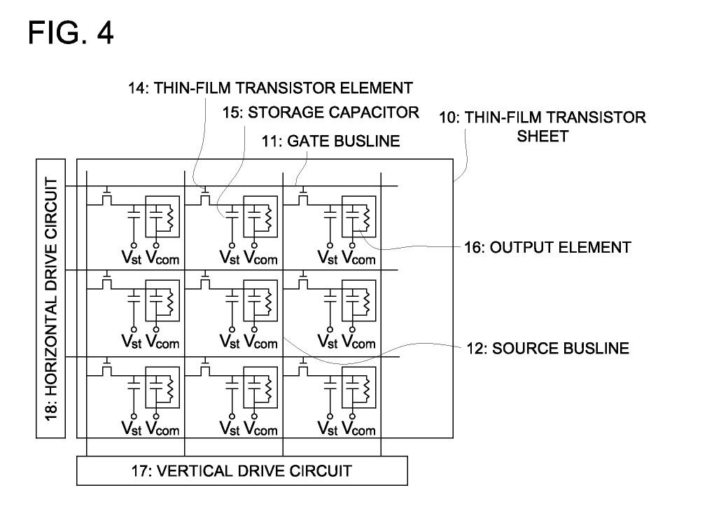

FIG. 4 shows a schematic equivalent circuit diagram of one example of a thin-film transistor sheet in which plural TFTs are arranged.

FIG. 4 shows a thin-film transistor sheet 14, in which plural display elements (pixels) or plural thin film transistor elements (TFTs) are arranged on for example, a plastic sheet (film).

The thin-film transistor sheet 10 comprises many of thin film transistor element 14 arranged in a matrix form. Numerical number 11 is a gate busline of the gate electrode of the thin-film transistor element 14, and numerical number 12 a source busline of the source electrode of the thin-film transistor element 14. Output element 16 is connected to the drain electrode of the thin-film transistor element 14. The output element 16 is for example, a liquid crystal or an electrophoresis element, and constitutes pixels in a display. In FIG. 4, liquid crystal as output element 16 is shown in an equivalent circuit diagram comprised of a capacitor and a resistor. Numerical number 15 shows a storage capacitor, numerical number 17 a vertical drive circuit, and numerical number 18 a horizontal drive circuit.

The process of the invention can be applied to manufacture of the above-described thin film transistor sheet in which thin film transistor elements are two-dimensionally arranged on a substrate.

In the invention, oxide semiconductor precursor is a material which is oxidation decomposed by for example, thermal oxidation or plasma oxidation to convert to oxide semiconductor. In the invention, the precursor is subjected to thermal patterning (selective heating) employing preferably microwave absorption, whereby the precursor is converted to oxide semiconductor at the heated portions.

### (Precursor)

In the invention, as the oxide semiconductor precursor, there is mentioned a metal atom-containing compound (hereinafter referred to as a metal compound). Examples of the metal compound include a metal salt, a metal halide and an organometallic compound.

Metals of the metal salt, the metal halide and the organometallic compound include Li, Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Cd, In, It, Sn, Sb, Cs, Ba, La, Hf, Ta, W, Tl, Pb, Bi, Ce, Pr, Nd, Pm, Eu, Gd, Tb, Dy, Ho, Er, Tm, Yb and Lu.

The metal salt is preferably one having a metal ion of In (indium), Sn (tin) or Zn (zinc). These metal salts may be used in combination.

It is preferred that the metal salt further has Ga (gallium) or Al (aluminum) as another metal.

As the metal salt, a metal nitrate, a metal sulfate, a metal phosphate, a metal carbonate, a metal acetate or a metal oxalate is preferred. As the metal halide, a metal chloride, a metal iodide or a metal bromide is suitably used.

Examples of the organometallic compound include a compound represented by the following Formula (I).

R¹xMR²yR³z Formula (I)

wherein M is a metal; R¹ represents an alkyl group; R² represents an alkoxy group; and R³ represents a β-diketone ligand, a β-ketocarboxylate ligand, a β-ketocarboxylic acid ligand or a ketooxy group, provided that when the valence of the metal M is m, x+y+Z=m, wherein x is an integer of from 0 to m or an integer of from 0 to m−1, y is an integer of from 0 to m, and z is an integer of from 0 to m.

Examples of the alkyl group of R¹ include a methyl group, an ethyl group, a propyl group, and a butyl group. Examples of the alkoxy group of R² include a methoxy group, an ethoxy group, a propoxy group, a butoxy group, and 3,3,3-trifluoropropoxy group. The hydrogen atom of the alkyl group may be substituted with a fluorine atom.

Examples of the β-diketone ligand of R³ include 2,4-pentanedione (acetyl acetone or acetoacetone), 1,1,1,5,5,5-hexamethyl-2,4-pentanedione, 2,2,6,6-tetramethyl-3,5-heptanedione, and 1,1,1-trifluoro-2,4-pentanedione. Examples of the β-keto carboxylate ligand of R³ include methyl acetoacetate, ethyl acetoacetate, propyl acetoacetate, ethyl trimethylacetoacetate and methyl trifluoroacetoacetate. Examples of the β-ketocarboxylic acid ligand of R³ include acetoacetic acid, and trimethylacetoacetic acid. Examples of the ketooxy group of R³ include an acetoxy group, a propionyloxy group, a butyryloxy group, an acryloyloxy group and a methacryloyloxy group. The carbon atom number of the groups or ligands described above is preferably not more than 18. These may be straight-chained or branched, and may be those in which the hydrogen atom is substituted with have a fluorine atom. “m” is an integer of preferably from 1 to 6, and more preferably from 2 to 4.

The organometallic compound is preferably one having at least one oxygen atom in the molecule, and more preferably one having, as R², at least one alkoxy group or one having, as R³, at least one of the β-diketone ligand, the β-ketocarboxylate ligand, the β-ketocarboxylic acid ligand and the ketooxy group.

Among the metal salts, a metal nitrate is preferred. The metal nitrate with high purity can be easily obtained and have high solubility to water which is used as a solvent. Examples of the nitrate include indium nitrate, tin nitrate, zinc nitrate, and gallium nitrate.

Among the oxide semiconductor precursors described above, a metal nitrate, a metal halide and a metal alkoxide are preferred. Typical examples thereof include indium nitrate, zinc nitrate, gallium nitrate, tin nitrate, aluminum nitrate, indium chloride, zinc chloride, tin (II) chloride, tin (IV) chloride, gallium chloride, aluminum chloride, indium tri-i-propoxide, zinc diethoxide, bis(dipivaloylmethanato)zinc, tin tetraethoxide, tin tetra-i-propoxide, gallium tri-i-propoxide, and aluminum tri-i-propoxide.

Among the metal salts above, metal nitrates are most preferable in reduced impurities or improved semiconductor performances.

The metal nitrates as the oxide semiconductor precursor can provide a thin film transistor with good performances when the oxide semiconductor precursor is heated at a relatively low temperature of from 100 to 400° C. to convert to a semiconductor.

These nitrates, when converted to an oxide semiconductor at a low temperature employing an electromagnetic wave (micro wave) for semiconductor conversion treatment, can shorten the duration of irradiation.

### (Formation of Oxide Semiconductor Precursor Layer)

In order to form a layer of the metal compound, i.e., the oxide semiconductor precursor, there can be employed various methods such as a known layer formation method, a vacuum deposition method, an ion cluster beam method, a low energy ion beam method, an ion plating method, a CVD method, a spattering method and an atmospheric plasma method. In the invention, a method is preferred which comprises coating continuously on a substrate a solution in which a metal salt, a metal halide or an organometallic compound is dissolved in an appropriate solvent, since productivity is greatly improved. As the metal compound, metal halides, metal nitrates, metal acetates or metal alkoxides are preferred in view of solubility.

Beside water, any solvent is used without limitations as long as it can dissolve a metal compound. Water, alcohols such as ethanol, propanol and ethylene glycol; ethers such as tetrahydrofuran and dioxane, esters such as methyl acetate and ethyl acetate; ketones such as acetone, methyl ethyl ketone and cyclohexanone, glycol ethers such as diethylene glycol monomethyl ether; acetonitrile; aromatic hydrocarbon solvents such as xylene and toluene; aromatic solvents such as o-dichlorobenzene, nitrobenzene and meta-cresol, aliphatic hydrocarbon solvents such as hexane, cyclohexane and tridecane; α-terpineol; halogenated alkane solvents such as chloroform and 1,2-dichloroethane; N-methylpyrrolidone; and carbon disulfide are suitably used.

When metal halides and/or metal alkoxides are used, solvents having a relatively high polarity are preferred, and among these, water, alcohols having a boiling point not more than 100° C. such as ethanol and propanol, acetonitrile or their mixture are preferred, since it is possible to lower the drying temperature and to coat on a resin substrate. A solvent containing 50% by weight or more of water or 50% by weight or more of alcohol is more preferred, and a solvent containing 50% by weight or more of water is most preferred.

Addition of chelating ligands, for example, multidentate ligands such as various alkanol amines, α-hydroxyketones and β-diketones in a solvent containing a metal alkoxide can stabilize the metal alkoxide and increase solubility of carboxylic acid salts. Accordingly, they are preferably added in such an amount that is not adversely affected.

As methods for applying a solution containing an oxide semiconductor precursor to a substrate, there are coating methods such as a spin coating method, a spray coating method, a blade coating method, a dip coating method, a cast coating method, a bar coating method and a die coating method; and coating methods in a broad sense such as letterpress printing, intaglio printing, lithographic printing or screen printing or ink jetting. An ink jet method or a spray coating method is preferred which enables thin layer coating.

The solution containing an oxide semiconductor precursor is applied to a substrate and then the solvent is evaporated at 50 to 150° C. to form an oxide semiconductor precursor layer. When the solution is applied to a substrate, the substrate also is preferably heated to the above temperature, since the application and drying can be simultaneously carried out.

### (Metal Composition Ratio)

A thin layer of a metal oxide semiconductor containing one or more of metal atoms selected from the above-mentioned metal atoms is formed according to the method of the invention. The metal oxide semiconductor may be single-crystalline, polycrystalline or amorphous, but preferably amorphous.

The formed metal oxide semiconductor preferably contains indium (In), tin (Sn) or zinc (Zn) as described above in the metal compound semiconductor precursor, and more preferably further contains gallium (Ga) or aluminum (Al).

When producing a solution of a semiconductor precursor containing these metals as the constituents, the ratio, metal A:metal B:metal C (by mole) preferably satisfies the following formula,

metal A:metal B:metal C=1:0.2 to 1.5:0 to 5 (by mole)

wherein metal A denotes a metal contained in a metal salt from indium salts and tin salts; metal B denotes a metal contained in a metal salt selected from gallium salts and aluminum salts; and metal C denotes a metal contained in a metal salt selected from zinc salts.

Since a metal nitrate is the most preferable as a metal salt, it is preferred that a nitrate of each metal is dissolved in a solvent containing water as a main component to prepare a coating liquid so that the molar ratio (A:B:C) of In, Sn (metal A), Ga, Al (metal B) and Zn (metal C) satisfies the above formula, followed by forming a precursor layer containing the metal salts by coating of the coating liquid.

In the above, it is preferred that the metal A is indium, the metal B is gallium, and the metal C is zinc.

The thickness of the semiconductor precursor layer is preferably from 1 to 200 nm, and more preferably from 5 to 100 nm.

### (Amorphous Oxide)

The oxide semiconductor produced by thermal oxidation may be single-crystalline, polycrystalline or amorphous, but is preferably amorphous.

The electron carrier density of an amorphous oxide, which is the metal oxide in the invention formed from the metal compound as the oxide semiconductor precursor, is less than 10¹⁸/cm³. Herein, the electron carrier density is a value measured at room temperature. The term “room temperature” means, for example, 25° C. Specifically, the room temperature is a certain temperature selected appropriately from a range of 0 to 40° C. The electron carrier density of the amorphous oxide in the invention is not required to be less than 10¹⁸/cm³ at the entire range of 0 to 40° C. For example, it suffices if the electron carrier density is less than 10¹⁸/cm³ at 25° C. A normally off type thin film transistor can be obtained with high yield at a further lower electron carrier density, i.e., at an electron carrier density of preferably 10¹⁷/cm³ or less, and more preferably 10¹⁶/cm³ or less.

The electron carrier concentration can be determined according to Hall Effect measurement.

The thickness of the metal oxide semiconductor layer is not specifically limited, and is generally not more than 1 gm, and preferably from 10 to 300 nm, although it is different depending on kinds of the semiconductor used and properties of the transistor obtained depend significantly on the thickness in many cases.

In the invention, kinds or composition of the precursor or manufacturing conditions of the semiconductor are controlled so that the electron carrier concentration falls within the range of for example, from 10¹²/cm³ to 10¹⁸/cm³. The electron carrier concentration is preferably from 10¹³/cm³ to 10¹⁷/cm³, and more preferably from 10¹⁵/cm³ to 10¹⁶/cm³.

The coating methods for the photoresist layer include known coating methods such as a dipping method, a spin coating method, a knife coating method, a bar coating method, a blade coating method, a squeeze coating method, a reverse roll coating method, a gravure roll coating method, a curtain coating method, a spray coating method and a die coating method.

The method for exposing the photoresist layer is not specifically limited. Flash exposure through a mask according to a xenon lamp, a halogen lamp or a mercury lamp or scanning exposure according to a laser can be carried. The laser is suitably employed, since the exposure spots can be easily condensed into minimum size, resulting in an image with high resolution.

The laser may be any of an ultraviolet laser, a visible laser and an infrared laser. Examples of the laser include a solid state laser such as a ruby laser, a YAG laser or a glass laser; a gaseous state laser such as a He—Ne laser, an argon ion laser, a Kr ion laser, a CO₂ laser, a CO laser, a He—Cd laser, an N₂ laser or an excimer laser; a semiconductor laser such as an InGaP laser, an AlGaAs laser, a GaAsP laser, an InGaAs laser, an InAsP laser, a CdSnP₂ laser or a GaSb laser; a chemical laser; and a dye laser. A semiconductor laser is preferred which has the emission wavelength in the infrared regions.

Next, the thin film transistor of the invention and another constituent constituting the thin film transistor will be explained.

The thickness of the semiconductor layer is not specifically limited, and is generally not more than 1 μm, and preferably from 10 to 300 nm, although it is different depending on kinds of the semiconductor used and properties of the transistor obtained depend significantly on the thickness in many cases.

Subsequently, another constituent constituting the thin film transistor will be explained.

### (Electrode)

In the invention, conductive materials used in the electrodes such as a source electrode, a drain electrode and a gate electrode, which constitute the thin film transistor, are not specifically limited as long as the materials have electric conductivity such that they can be practically used for electrodes. As the conductive materials are utilized platinum, gold, silver, nickel, chromium, copper, iron, tin, antimony lead, tantalum, indium, palladium, tellurium, rhenium, iridium, aluminum, ruthenium, germanium, molybdenum, tungsten; electrode materials having an electromagnetic wave absorbing capability such as tin-antimony oxide, indium-tin oxide (ITO) or fluorine-doped zinc oxide; zinc, carbon, graphite, glassy carbon, silver paste and carbon paste; lithium, beryllium, sodium, magnesium, potassium, calcium, scandium, titanium, manganese, zirconium, gallium, niobium, sodium, sodium-potassium alloy, magnesium, lithium, aluminum, magnesium/copper mixtures, magnesium/silver mixtures, magnesium/aluminum mixtures, magnesium/indium mixtures, aluminum/aluminum oxide mixtures, and lithium/aluminum mixtures.

As the conductive materials, conductive polymers or metal particles are also utilized.

For example, a conductive paste known in the art may be utilized as a dispersion containing metal particles, but the dispersion is preferred which contains metal particles with a particle diameter of from 1 to 50 nm, and preferably from 1 to 10 nm. As a method for forming an electrode from the metal particles, the method as described can be used, and as materials for metal particles there are mentioned the metals described above.

### (Method for Forming Electrode)

As the method for forming the electrode, there are a method in which the electrode is formed from the conductive materials described above through a mask according to a vacuum deposition method or a sputtering method, a method in which the electrode is formed according to a known photolithography or lift-off method from an electrically conductive layer formed according to a vacuum deposition method or a sputtering method, and a method in which a resist is formed on a film of a metal such as aluminum or copper via heat transfer or ink-jet printing, followed by etching. Further, patterning may be directly carried out according to an ink-jet printing method using a conductive polymer solution or dispersion or a dispersion containing metal particles, or the electrode may be formed from a coated layer according to lithography or laser ablation. Still further, it is possible to utilize a method in which the patterning is carried out via printing methods such as letterpress, intaglio, lithographic, or screen printing, using a conductive ink or paste containing conductive polymers or metal particles.

As a method for forming an electrode such as a source, a drain or a gate electrode, or a gate or a source busline without carrying out pattering of a metal thin film using a light sensitive resin as in etching or lift-off, there is known one employing an electroless plating method.

In the method for forming electrodes via the electroless plating method, as described in Japanese Patent O.P.I. Publication No. 2004-158805, a liquid containing a plating catalyst inducing electroless plating on reaction with a plating agent is patterned on portions where an electrode is provided, for example, via a printing method (including an ink-jet method), followed by allowing the plating agent to be brought into contact with the portions where an electrode is provided. Thus, electroless plating is carried out on the above portions via contact of the catalyst with the plating agent to form an electrode pattern.

The catalyst and the plating agent may reversely be employed in such electroless plating, and also pattern formation may be conducted using either thereof. However, it is preferred to employ a method of forming a plating catalyst pattern and then applying a plating agent thereto.

As the printing method, printing such as screen printing, lithographic printing, letterpress printing, intaglio printing or ink jet printing is employed.

### (Gate Insulating Layer)

Various insulating films may be employed as the gate insulating film (layer) of the thin film transistor. The insulating layer is preferably an inorganic oxide layer comprised of an inorganic oxide with high dielectric constant. Examples of the inorganic oxide include silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth niobate tantalate, and yttrium trioxide. Of these, silicon oxide, aluminum oxide, tantalum oxide or titanium oxide is preferred. An inorganic nitride such as silicon nitride or aluminum nitride can be also suitably used.

As methods for forming the above layer, there are mentioned of a dry process including a vacuum deposition method, a molecular beam epitaxial growth method, an ion cluster beam method, a low energy ion beam method, an ion plating method, a CVD method, a sputtering method and an atmospheric pressure plasma method, and a wet process including a coating method such as a spray coating method, a spin coating method, a blade coating method, a dip coating method, a casting method, a roll coating method, an bar coating method or a die coating method, and a patterning method such as a printing method or an ink-jet method. These methods can be suitably applied due to kinds of materials used.

As the typical wet process can be used a method of coating an inorganic oxide particle dispersion, prepared by dispersing inorganic oxide particles in an organic solvent or water optionally in the presence of a dispersant such as a surfactant, followed by drying, or a so-called sol gel method of coating a solution of an oxide precursor such as an alkoxide, followed by drying.

Among the above, the preferred is the atmospheric pressure plasma method.

It is preferred that the gate insulating layer is comprised of an anodized film or of a mixed film of an anodized film and an insulating film. The anodized film is preferably subjected to sealing treatment. The anodized film is formed by anodizing a metal capable of being anodized according to a known method.

Examples of the metal capable of being anodized include aluminum and tantalum. An anodization treatment method is not specifically limited and the known anodization treatment method can be used.

Examples of an organic compound used in an organic compound layer include polyimide, polyamide, polyester, polyacrylate, photocurable resins of the photo-radical polymerization or photo-cation polymerization type, a copolymer containing an acrylonitrile unit, polyvinyl phenol, polyvinyl alcohol, and novolak resin.

The inorganic oxide layer or the organic oxide layer can be used in combination or superposed on each other. The thickness of the insulating layer above is generally 50 nm to 3 μm, and preferably from 100 nm to 1 μm.

### (Protective Layer)

A protective layer can be provided on an organic thin film transistor element. As the protective layer, there are mentioned a layer of inorganic oxides or nitrides, a layer of a metal such as aluminum, a polymer layer having a low permeability to gas and their laminates. The protective layer increases durability of the organic thin film transistor. As a method for forming the protective layer, there is mentioned the same method as described above in the gate insulating layer. The protective layer may be provided according to a method in which a polymer film provided with various inorganic oxides is laminated on the thin film transistor.

### (Substrate)

Various materials are usable as substrate materials to constituting a substrate. For example, employed may be ceramic substrates such as glass, quartz, aluminum oxide, sapphire, silicon nitride and silicon carbide; and semiconductor substrates such as silicon, germanium, gallium arsine and gallium nitrogen; paper; and unwoven cloth. In the present invention, it is preferred that the substrate is composed of resins. For example, a plastic film sheet is usable. Examples of the plastic film include film comprised of, for example, polyethylene terephthalate (PET), polyethylene naphthalate (PEN), polyethersulfone (PES), polyetherimide, polyether ether ketone, polyphenylene sulfide (PPS), polyallylate, polyimide (PI), Polyamideimide (PAI), polycarbonate (PC), cellulose triacetate (TAC), or cellulose acetate propionate (CAP). Use of such a plastic film makes it possible to decrease weight, to enhance portability, and to enhance durability against impact due to its flexibility, as compared to glass.

### EXAMPLES

Next, the present invention will be explained employing examples, but is not specifically limited thereto. In the examples,

### Example 1

A bottom gate bottom contact type thin film transistor was manufactured according to a process as shown in FIGS. 1.1 through 1.7 (in section).

A 300 nm thick aluminum layer was formed entirely on the surface of a glass substrate as a substrate 1 employing a sputtering method, followed by etching according to photolithography, whereby a gate electrode 2 (with a thickness of 100 nm) was formed.

Subsequently, a gate insulating layer 3 with a thickness of 200 nm comprised of silicon oxide was formed according to an atmospheric pressure plasma CVD method. As an atmospheric pressure plasma processing apparatus, one as shown in FIG. 6 disclosed in Japanese Patent O.P.I. Publication No. 2003-303520 was employed.

### (Gases Used)

Inert gas: helium 98.25% by volume
Reactive gas: oxygen gas 1.5% by volume
Reactive gas: tetraethoxysilane vapor 0.25% by volume (bubbled with helium gas)

### (Discharge Conditions)

High frequency power source: 13.56 MHz
Discharge power: 10 W/cm²

### (Electrode Conditions)

The electrode was a grounded roll electrode having a dielectric material (specific dielectric constant: 10) with a smooth surface of an Rmax of 5 μm, wherein a stainless steel jacket roll base material having a cooling device employing chilled water was coated with a 1 mm thick alumina layer via ceramic spraying, further coated with a solution prepared by diluting tetramethoxysilane with ethyl acetate, and dried, followed by sealing treatment via ultraviolet irradiation. In contrast, a hollow square-shape stainless pipe having the same dielectric material as above was prepared in the same manner as above, whereby a voltage application electrode was obtained.

Subsequently, chromium was vapor evaporated through a mask to form a source electrode 4 and a drain electrode 5 (FIG. 1.1).

The source and drain electrodes each had a width of 10 μm and a length (channel width) of 50 μm and a thickness of 50 nm. The distance (channel length) between the source electrode and the drain electrode was 15 μm.

An aqueous solution containing 10% by weight of a mixture of indium nitrate, zinc nitrate and gallium nitrate (with a mixing ratio by mole of 1:1:1 in terms of metal) for a semiconductor precursor layer was spin coated on the resulting materials (at a rate of 3000 rpm) and dried at 150° C. for 30 minutes to form a semiconductor precursor layer 6′ (FIG. 1.2).

Further, the following light sensitive layer coating solution was spin coated on the resulting semiconductor precursor layer 6′, and dried at 100° C. for 2 minutes to form a photoresist layer 14 (FIG. 1.3).

| | | |
|---|---|---|
| Dye A | 1 | part |
| Novolak resin (novolak resin prepared by co- | 70 | parts |
| polycondensation of phenol and a mixed cresol of | | |
| m-cresol and p-cresol with formaldehyde (Mn = 500, | | |
| Mw = 2500; phenol/m-cresol/p-cresol = 20/48/32) | | |
| Photoacid generating agent (2-Trichloromethyl-5-[β- | 3 | parts |
| (2-benzofuryl)vinyl]-1,3,4-oxadiazole) | | |
| Compound B | 20 | parts |
| Fluorine-containing surfactant (S-381 produced by | 0.5 | parts |
| Asahi Glass Co., Ltd.) | | |
| Methyl lactate | 700 | parts |
| Methyl ethyl ketone | 200 | parts |

### (Synthesis of Compound B)

A mixture of 1.0 mole of 1,1-dimethoxycyclohexane, 1.0 mole of triethylene glycol, 0.003 mole of p-toluene sulfonic acid hydrate, and 500 ml of toluene was reacted at 100° C. for one hour while stirring, was gradually heated to 150° C., and further reacted at 150° C. for 4 hours. Methanol produced was removed during reaction. Thereafter, the resulting reaction mixture was cooled and the reaction product produced was washed with an aqueous 1% NAOH solution and then with an aqueous 1 mole NAOH solution. The mixture solution was washed with an aqueous sodium chloride solution and then dried over anhydrous potassium carbonate, followed by concentration under reduced pressure. The resulting product was dried at 80° C. for 10 hours under vacuum pressure to obtain waxy compound. The weight average molecular weight Mw of the compound was 1500 in terms of styrene, measured according to GPC.

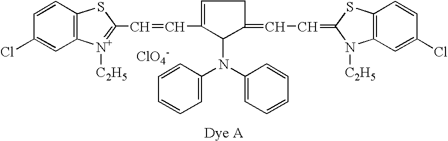

Then, exposure was carried out according to a semiconductor layer (active layer) pattern so that the portions other than the active layer portions are exposed (FIG. 1.4), using a 100 mW semiconductor laser with an 830 nm emission wavelength at an energy density of 200 mJ/cm², followed by development with an alkaline developing solution (a 20% diethanolamine aqueous solution) whereby the photoresist layer at exposed portions was removed and the photoresist layer 14a at active layer portions was allowed to remain (FIG. 1.5). During the development, the semiconductor precursor layer at the exposed portions was removed together with the photoresist layer at the exposed portions with the alkaline developing solution developer (FIG. 1.6).

Subsequently, the remaining photoresist layer 14a was removed with MEK (methyl ethyl ketone), and heated at 250° C. for 15 minutes in an oven under the same oxygen pressure as atmosphere to convert the precursor to an oxide semiconductor, whereby a semiconductor layer 6 was formed (FIG. 1.7).

The semiconductor precursor layer was changed to a transparent semiconductor layer 6. Thus, a bottom gate and top contact type thin film transistor was manufactured.

The thin film transistor thus obtained was evaluated.

It has proved that the thin film transistor was effectively driven, and exhibited an n-type enhancement operation. When the drain bias was set at 10V and the gate bias was scanned from −10 to +20V, the drain current increase (transmission property) was observed. Mobility evaluated from the saturation region was 2 cm²/Vs, and the on/off ratio was six-digit or more.

### Example 2

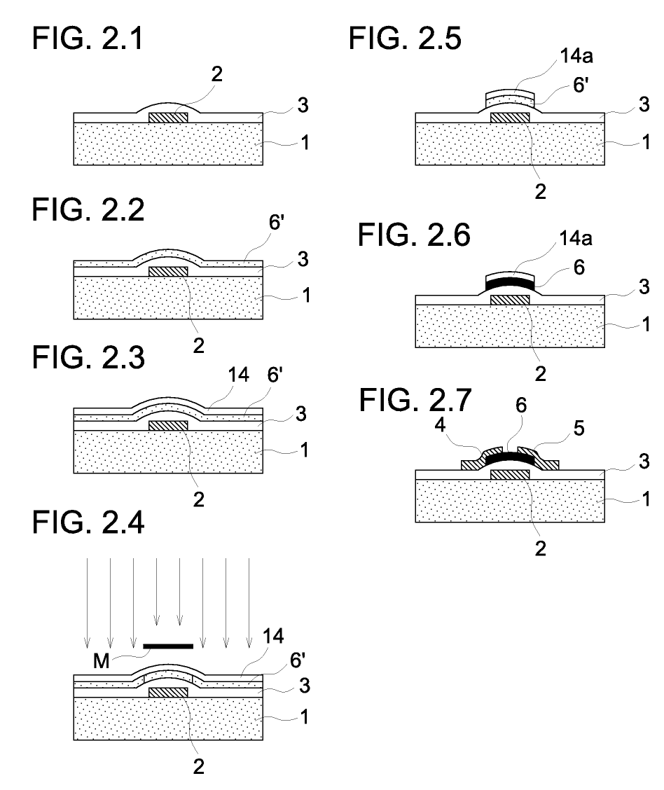

A thin film transistor was manufactured according to a process as shown in FIGS. 2.1 through 2.7 in section.

A polyethersulfone resin film (200 μm) was used for resin substrate 1, and subjected to corona discharge under a condition of 50 W/m²/min. Then, a subbing layer was formed to enhance adhesion as follows.

### (Subbing Layer Formation)

A coating solution having the following composition was coated on the substrate, dried at 90° C. for 5 minutes to obtain a dry thickness of 2 μm, and cured using a high pressure mercury lamp of 60 W/cm for 4 seconds at a distance of 10 cm from the lamp.

| | |
|---|---|
| Dipentaerythritolhexaacrylate monomer | 60 g |
| Dipentaerythritolhexaacrylate dimmer | 20 g |
| Trimer or more of dipentaerythritolhexaacrylate | 20 g |
| Diethoxybenzophenone UV initiator | 2 g |
| Silicone-containing surfactant | 1 g |
| Methyl ethyl ketone | 75 g |
| Methylpropylene glycol | 75 g |

Further, the resulting layer was subjected to atmospheric pressure plasma processing under the following conditions to form a silicon oxide layer with a thickness of 50 nm as a subbing layer.

(Gases used)

| | |
|---|---|
| Inert gas | helium 98.25% by volume |
| Reactive gas | oxygen gas 1.5% by volume |
| Reactive gas | tetraethoxysilane vapor 0.25% by volume |
| (bubbled with helium gas) | |

(Discharge conditions)

| | |
|---|---|
| Discharge power | 10 W/cm² |

### (Electrode Conditions)

The electrode was a grounded roll electrode having a dielectric material (specific dielectric constant: 10) with a smooth surface of an Rmax of 5 μm, wherein a stainless steel jacket roll base material having a cooling device employing chilled water was coated with a 1 mm thick alumina layer via ceramic spraying, further coated with a solution prepared by diluting tetramethoxysilane with ethyl acetate, and dried, followed by sealing treatment via ultraviolet irradiation. In contrast, a hollow square-shape stainless pipe having the same dielectric material as above was prepared in the same manner as above, whereby a voltage application electrode was obtained.

Subsequently, a gate electrode 2 was formed on the subbing layer. A 300 nm thick aluminum layer was formed entirely on the surface thereof employing a sputtering method, followed by etching according to photolithography, whereby a gate electrode 2 was formed.

### (Anodized Film Formation Process)

After formation of the gate electrode 2, the substrate was sufficiently washed, and then anodization was carried out in a 10% by weight ammonium phosphate aqueous solution employing direct current supplied from a 30 V constant voltage power supply for 2 minutes to form an anodized film with a thickness of 120 nm (not illustrated).

Then, a silicon dioxide layer with a thickness of 30 nm was further formed at a film temperature of 200° C. according to the atmospheric pressure plasma method as described above to form a gate insulating layer 3 (FIG. 2.1) in which the thickness was 150 nm together with the anodized aluminum film. In FIG. 2.1, the subbing layer is not illustrated.

### (Semiconductor Precursor Layer Formation)

An aqueous solution containing 10% by weight of a mixture of indium nitrate, zinc nitrate and gallium nitrate (with a mixing ratio by mole of 1:1:1 in terms of metal) was spin coated on the gate insulating layer (at a rate of 3000 rpm) and dried at 150° C. for ten minutes to form a semiconductor precursor layer 6′ (FIG. 2.2).

The photoresist layer 14 used in Example 1 was coated on the semiconductor precursor layer 6′ (FIG. 2.3) and exposed in the same manner as in Example 1 (FIG. 2.4). Subsequently, the exposed layer was developed with an alkaline developing solution to remove the photoresist layer at exposed portions and leave the photoresist layer 14a at active layer portions, during which the semiconductor precursor layer 6′ at exposed portions was also removed with the developer (FIG. 2.5).

Subsequently, the remaining photoresist layer was removed with MEK (methyl ethyl ketone), and heated at 280° C. for 30 minutes in an oven under the same oxygen pressure as atmosphere to form a semiconductor layer 6 (FIG. 2.6).

Subsequently, gold was vacuum deposited on the semiconductor layer 6 through a mask to form a source electrode 4 and a drain electrode 5 each having a width of 10 μm and a length of 50 μm and a thickness of 50 nm (FIG. 2.7). The distance (channel length) between the source electrode 4 and the drain electrode 5 was 15 μm.

The thin film transistor thus obtained was evaluated. It has proved that the thin film transistor was effectively driven, and exhibited an n-type enhancement operation. When the drain bias was set at 10V and the gate bias was scanned from −10 to +20V, the drain current increase (transmission property) was observed. Mobility evaluated from the saturation region was 1.5 cm²/Vs, and the on/off ratio was six-digit or more.

### Example 3

A thin film transistor was manufactured in the same manner as in Example 1 above, except that the semiconductor precursor layer formation was changed to the following semiconductor precursor layer formation.

### (Semiconductor Precursor Layer Formation)

The aqueous solution for a semiconductor precursor layer in Example 1 was replaced with the following solution. A solution was prepared in which tin chloride (with a purity of 99.995%, produced by Sigma Aldrich Japan, Inc.) and zinc chloride (with a purity of 99.995%, produced by Sigma Aldrich Japan, Inc.) were dissolved in a concentration of 0.02 mol in a mixture solvent of 60% of alcohol and 40% of acetonitrile employing ultrasonic waves to have an Sn and Zn composition ratio of 1:1. The resulting solution was spin coated at 1500 rpm on a substrate provided with a gate insulating layer to form a semiconductor precursor layer.

The thin film transistor thus obtained was effectively driven, and exhibited an n-type enhancement operation. When the drain bias was set at 10V and the gate bias was scanned from −10 to +20V, the drain current increase (transmission property) was observed. Mobility evaluated from the saturation region was 1 cm²/Vs, and the on/off ratio was five-digit or more.

### Example 4

A bottom gate bottom contact type thin film transistor was manufactured according to a process as shown in FIGS. 1.1 through 1.7.

As semiconductor precursors, indium nitrate [In(NO₃)₃], zinc nitrate [Zn(NO₃)₂] and gallium nitrate [Ga(NO₃)₃] were used, the content ratio of the nitrates being varied. Thus, thin film transistors having a different semiconductor composition were prepared.

A 300 nm thick aluminum layer was formed entirely on the surface of a glass substrate A as a substrate 1 employing a sputtering method, followed by etching according to photolithography, whereby a gate electrode 2 (with a thickness of 100 nm) was formed.

Subsequently, a gate insulating layer 3 with a thickness of 200 nm comprised of silicon oxide was formed according to an atmospheric pressure plasma CVD method. As an atmospheric pressure plasma processing apparatus, one as shown in FIG. 6 disclosed in Japanese Patent O.P.I. Publication No. 2003-303520 was employed.

(Gases used)

| | |
|---|---|
| Inert gas | helium 98.25% by volume |
| Reactive gas | oxygen gas 1.5% by volume |
| Reactive gas | tetraethoxysilane vapor 0.25% by volume |
| (bubbled with helium gas) | |

(Discharge conditions)

| | | |
|---|---|---|
| High frequency power source | 13.56 | MHz |
| Discharge power: | 10 | W/cm² |

### (Electrode Conditions)

The electrode was a grounded roll electrode having a dielectric material (specific dielectric constant: 10) with a smooth surface of an Rmax of 5 μm, wherein a stainless steel jacket roll base material having a cooling device employing chilled water was coated with a 1 mm thick alumina layer via ceramic spraying, further coated with a solution prepared by diluting tetramethoxysilane with ethyl acetate, and dried, followed by sealing treatment via ultraviolet irradiation. In contrast, a hollow square-shape stainless pipe having the same dielectric material as above was prepared in the same manner as above, whereby a voltage application electrode was obtained.

Subsequently, chromium was vapor evaporated through a mask to form a source electrode 4 and a drain electrode 5 (FIG. 1.1).

The source and drain electrodes each had a width of 10 μm and a length (channel width) of 50 μm and a thickness of 50 nm. The distance (channel length) between the source electrode and the drain electrode was 15 μm.

Next, a metal salt (semiconductor precursor) coating solution was prepared.

Nitrates of In, Ga and Zn were dissolved in a mixture solution of 90% of water and 10% of ethanol to be in a total amount of 10% by weight, stirred at room temperature for 10 minutes, and further subjected to ultrasonic treatment for 10 minutes.

The resulting solution was filtered with a filter with a mesh diameter of 0.2μ, and further subjected to ultrasonic treatment for 10 minutes under reduced pressure for defoaming. Thus, a metal salt coating solution was prepared.

The metal salt coating solution was ejected onto the semiconductor channel regions employing a piezo type ink jet while the temperature of the substrate was maintained at 100° C. to form a semiconductor precursor layer 6′ (FIG. 1.2).

The photoresist layer 14 used in Example 1 was coated on the semiconductor precursor layer 6′ (FIG. 1.3) and exposed in the same manner as in Example 1 (FIG. 1.4). Subsequently, the exposed layer was developed with an alkaline developing solution to remove the photoresist layer at exposed portions and leave the photoresist layer 14a at active layer portions, during which the semiconductor precursor layer at exposed portions was removed with the developer (FIG. 1.5).

Subsequently, the remaining photoresist layer was removed with MEK (methyl ethyl ketone), dried at 100° C., and further dried at 150° C.

A 110 nm ITO layer was formed on a glass substrate by sputtering to prepare a glass substrate B. Then, the glass substrate A was superposed on the glass substrate B so that the surface of the glass substrate A opposite the oxide semiconductor layer contacted the ITO layer of the glass substrate B. Then, a microwave was irradiated to the glass surface of the glass substrate B of the resulting laminates, and the semiconductor precursor layer was calcined at 300° C. through indirect heat generated from the ITO of the glass substrate B, whereby the semiconductor precursor layer was converted to a semiconductor layer 6 (with a thickness of 50 nm).

The glass surface was subjected to microwave irradiation at a power of 500 W using a multi-mode type 2.45 GHz microwave irradiator (μ-reactor, produced by Shikoku Instrumentation CO., LTD.) under an atmospheric pressure in an ambient atmosphere, whereby the semiconductor precursor layer 6′ was calcined and converted to semiconductor layer 6. The microwave irradiation was carried out so that, after elevating the layer surface temperature to 300° C. at an output power of 500 W, the surface temperature was kept at 300° C. for 30 minutes by PID controlling the output power of the microwave, only the semiconductor side surface being protected with a heat insulating material and the surface temperature being measured through a surface thermometer employing a thermocouple.

Subsequently, a source electrode and a drain electrode were formed by vacuum deposition of gold through a mask. Thus, thin film transistors were manufactured.

The source and drain electrodes each had a width of 100 μm and a thickness of 100 nm. The channel width W was 3 mm, and the channel length L was 20 μm.

The metal salt coating solutions in which the content ratio by mole (in terms of metal) of the nitrate salt of each of In, Ga and Zn was varied as shown in Table 1 were prepared. The content ratio by mole of each metal was determined both when the metal salt coating solution was prepared and after the oxide semiconductor layer was formed by calcination. The metal content ratio (by mole) of the formed semiconductor layer was measured through ESCA and determined as the average value of ratio data obtained except for data both in the top surface and in the vicinity of the interface with the insulating layer.

Thus, thin film transistors 4-1 through 4-11 as shown in Table 1 were manufactured.

The voltage between the source and drain electrodes being set at 40V and the gate voltage being scanned from −40 to +40V, mobility μ (cm²/Vs), on/off ratio (in terms of log value) and threshold value Vth of each of thin film transistors 4-1 through 4-11 were estimated. The mobility was estimated from the saturation region, and the threshold value Vth was estimated as the value of the gate bias obtained by extrapolating the √Id value to √Id=0 in the relationship between the gate bias and the square root √Id of the drain current. The results are shown in Table 1.

TABLE 1

| | In:Ga:Zn Ratio | | | | |
|---|---|---|---|---|---|
| Thin Film | (by mole) | | Mobility | On/off | |
| Transistor | a) | b) | (cm²/Vs) | Ratio | Vth |
| 4-1 | 1:0.1:1 | 1:0.2:0.9 | 2 | 3.3 | −15.0 |
| 4-2 | 1:0.2:1 | 1:0.4:0.9 | 2.5 | 5.0 | −8.0 |
| 4-3 | 1:0.5:1 | 1:1.1:0.9 | 4.5 | 7.5 | 2.0 |
| 4-4 | 1:1:1 | 1:2:1 | 3.0 | 7.0 | 2.4 |
| 4-5 | 1:1.5:1 | 1:2.3:1 | 1.5 | 6.7 | 2.0 |
| 4-6 | 1:0.5:2 | 1:1:1.8 | 4 | 6.1 | −1.0 |
| 4-7 | 1:0.5:4 | 1:0.9:3.5 | 5.7 | 5.0 | −2.0 |
| 4-8 | 1:0.5:5 | 1:0.9:4.5 | 5.7 | 3.5 | −5.5 |
| 4-9 | 1:0.5:5.5 | 1:0.9:4.8 | 5 | 2.8 | −7.0 |
| 4-10 | 1:0.5:0.7 | 1:1:0.5 | 5 | 6.8 | 1.5 |
| 4-11 | 1:0.5:0 | 1:1:0 | 6 | 7.5 | 1.2 |

a) Ratio obtained when the metal salt coating solution was prepared
b) Ratio obtained after the oxide semiconductor layer was formed by calcination

What is claimed is:

1. A process for manufacturing a thin film transistor, the process comprising the steps of:
providing an oxide semiconductor precursor solution for an oxide semiconductor layer in which the oxide semiconductor precursor is dissolved in a solvent;
coating the oxide semiconductor precursor solution on a substrate to form an oxide semiconductor precursor layer;
patterning the oxide semiconductor precursor layer so that the oxide semiconductor precursor layer remains at portions where the oxide semiconductor layer is to be formed; and
heating the remaining oxide semiconductor precursor layer to form the oxide semiconductor layer.

2. The process of claim 1, wherein the solvent is at least one selected from the group consisting of water, ethanol, propanol, ethylene glycol, tetrahydrofuran, dioxane, methyl acetate, ethyl acetate, acetone, methyl ethyl ketone, cyclohexanone, diethylene glycol monomethyl ether, acetonitrile, xylene, toluene, o-dichlorobenzene, nitrobenzene, meta-cresol, hexane, cyclohexane, tridecane, α-terpineol, chloroform, 1,2-dichloroethane, N-methylpyrrolidone and carbon disulfide.

3. The process of claim 1, wherein the solvent contains 50% or more by weight of water or 50% by weight or more of an alcohol.

4. The process of claim 1, wherein the coating is carried out according to a spin coating method, a spray coating method, a blade coating method, a dip coating method, a cast coating method, a bar coating method, a die coating method, letterpress printing, intaglio printing, lithographic printing, screen printing or ink jetting.

5. The process of claim 1, wherein the patterning comprises employing an ink jet method, a screen printing method, an ablation method or a photoresist method.

6. The process of claim 1, wherein the patterning comprises the steps of forming a photoresist layer on the oxide semiconductor precursor layer; pattern-wise exposing the photoresist layer; and developing the exposed photoresist layer with a developing solution so that the photoresist layer on the oxide semiconductor precursor layer at portions where the oxide semiconductor layer is to be formed remains unremoved and an unnecessary oxide semiconductor precursor layer is removed during development.

7. The process of claim 6, wherein the photoresist layer is formed from a negative working photoresist, a positive working photoresist or a laser-sensitive photoresist.

8. The process of claim 6, wherein the developing solution contains 50% or more by weight of water or 50% by weight or more of alcohol.

9. The process of claim 6, after the heating, further comprising the step of removing the remaining photoresist layer with a solution containing at least one selected from the group consisting of alcohols, ethers, esters, ketones and glycol ethers.

10. The process of claim 9, wherein the solution contains ketones.

11. The process of claim 1, wherein the heating is carried out employing at least one selected from an infrared heater, an electric oven, a dry heat block and a microwave.

12. The process of claim 1, wherein the heating is carried out according to at least irradiation of microwave with a frequency of from 0.3 to 50 GHz.

13. The process of claim 1, wherein the oxide semiconductor precursor comprises a metal ion of In, Sn or Zn.

14. The process of claim 1, wherein the oxide semiconductor precursor comprises a metal ion of Ga or Al.

15. The process of claim 1, wherein the oxide semiconductor precursor comprises at least one metal salt selected from the group consisting of a metal nitrate, a metal sulfate, a metal phosphate, a metal carbonate, a metal acetate and a metal oxalate.

16. The process of claim 15, wherein the oxide semiconductor precursor comprises a metal nitrate.

17. The process of claim 1, wherein the oxide semiconductor precursor solution contains metal A, metal B, and metal C so as to satisfy the following formula, metal A:metal B:metal C=1:0.2 to 1.5:0 to 5 (by mole) wherein metal A denotes a metal contained in a metal salt selected from indium salts and tin salts; metal B denotes a metal contained in a metal salt selected from gallium salts and aluminum salts; and metal C denotes a metal contained in a metal salt selected from zinc salts.

18. The process of claim 17, wherein the metal A is indium, the metal B is gallium, and the metal C is zinc.

19. The process of claim 1, wherein the oxide semiconductor precursor comprises indium nitrate, gallium nitrate and zinc nitrate, the solvent contains 50% by weight or more of water or 50% by weight or more of alcohol, and the heating is carried out according to irradiation of microwave with a frequency of from 0.3 to 50 GHz.

20. The process of claim 19, wherein the solvent contains 50% by weight or more of water.
